(19) United States
(12) Patent Application Publication
(10) Pub. No.: US 2026/0211449 A1
(43) Pub. Date: Jul. 23, 2026

(54) SIGNAL GENERATOR AND METHOD FOR VERIFYING ASYNCHRONOUS INTERFACE CIRCUIT

(71) Applicant: Realtek Semiconductor Corp., HsinChu (TW)

(72) Inventors: XIANGHUA SHEN, Suzhou City (CN); Meng Liu, Suzhou City (CN); ZIchen Wang, Suzhou CIty (CN); Yanmei Feng, Suzhou CIty (CN); Jiaxi He, Suzhou CIty (CN)

(73) Assignee: Realtek Semiconductor Corp., HsinChu (TW)

(21) Appl. No.: 19/454,438

(22) Filed: Jan. 21, 2026

(30) Foreign Application Priority Data
Jan. 23, 2025 (CN) 202510108701.5

(51) Int. Cl. G06F 1/04

(52) U.S. Cl. CPC G06F 1/04

(57) ABSTRACT

A signal generator and a method for verifying an asynchronous interface circuit are provided, where the signal generator includes a frame modulator, a clock generator, an interface selector and a checking module. The frame modulator generates a modulated signal according to a frame control parameter, and the clock generator generates a clock signal according to a clock control parameter. The interface selector generate a receiving test signal according to an interface control parameter, the modulated signal and the clock signal, where the signal generator utilize a reference model to generate a reference signal according to the receiving test signal, and the asynchronous interface circuit generates a transmitting test signal according to the receiving test signal. In addition, the checking module generates at least one verification result according to the reference signal and the transmitting test signal.

### BACKGROUND OF THE INVENTION

### 1. Field of the Invention

The present invention is related to verification of digital chips, and more particularly, to a signal generator and a method for verifying an asynchronous interface circuit such as an asynchronous interface circuit for transmitting Ethernet packets.

### 2. Description of the Prior Art

In a communication network, transmitted Ethernet packets typically pass through a plurality of asynchronous interfaces. Compared with synchronous interfaces, asynchronous interfaces are more prone to problems such as transmission errors or loss of data packets, which results in degradation of communication quality or even interruption of network connections. Thus, chips equipped with asynchronous interfaces need to undergo proper verification before mass production, to ensure that the asynchronous interfaces in the chips can operate properly. Verification methods of related arts typically verify the entire chip. It is therefore difficult to perform complete verification specifically for the asynchronous interfaces therein (e.g. simulating various scenarios where errors may occur). Further, there is a lack of testing regarding performance limits of the asynchronous interfaces. In addition, the related arts typically can only perform complete verification of the asynchronous interfaces after the chip manufacturing is completed. This results in a lack of sufficient adjustment and correction means when problems with the asynchronous interfaces are discovered, leading to poor efficiency in design, verification, and modification of the chips.

Thus, there is a need for a novel verification mechanism to implement specialized testing for asynchronous interfaces in an early stage of product development, to thereby improve the verification efficiency and simplify the development cycle of the chips.

### SUMMARY OF THE INVENTION

An objective of the present invention is to provide a signal generator and a method for verifying an asynchronous interface circuit such as an asynchronous interface circuit for transmitting Ethernet packets, which can solve the problems of the related art without introducing any side effect or in a way that is less likely to introduce side effects.

At least one embodiment of the present invention provides a signal generator for verifying an asynchronous interface circuit. The signal generator comprises a frame modulator, a clock generator, an interface selector and a checking module. The frame modulator is configured to generate a modulated signal according to at least one frame control parameter. The clock generator is configured to generate a clock signal according to at least one clock control parameter. The interface selector is configured to generate a receiving test signal to the asynchronous interface circuit according to at least one interface control parameter, the modulated signal and the clock signal, where the signal generator utilizes a reference model to generate a reference signal according to the receiving test signal, and the asynchronous interface circuit generates a transmitting test signal according to the receiving test signal. In addition, the checking module is configured to generate at least one verification result according to the reference signal and the transmitting test signal.

At least one embodiment of the present invention provides a method for verifying an asynchronous interface circuit, where the asynchronous interface circuit is coupled to a signal generator. The method comprises: utilizing a frame modulator of the signal generator to generate a modulated signal according to at least one frame control parameter; utilizing a clock generator of the signal generator to generate a clock signal according to at least one clock control parameter; utilizing an interface selector of the signal generator to generate a receiving test signal to the asynchronous interface circuit according to at least one interface control parameter, the modulated signal and the clock signal; utilizing a reference model of the signal generator to generate a reference signal according to the receiving test signal; utilizing the asynchronous interface circuit to generate a transmitting test signal according to the receiving test signal; and utilizing a checking module of the signal generator to generate at least one verification result according to the reference signal and the transmitting test signal.

The signal generator and the method provided by the embodiments of the present invention can simulate various packet receiving conditions of the asynchronous interface circuit via different settings of the control parameters, to thereby ensure that the asynchronous interface circuit can properly operate under these conditions and test the performance limit of the asynchronous interface circuit. In addition, the embodiments of the present invention will not significantly increase additional costs. Thus, the present invention can solve the problem of the related art without introducing any side effects or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a structure of a media access control (MAC) frame of Ethernet according to an embodiment of the present invention.

FIG. 2 is a diagram illustrating an asynchronous interface circuit according to an embodiment of the present invention.

FIG. 3 is a diagram illustrating a MAC frame transmitted between two devices via a physical medium according to an embodiment of the present invention.

FIG. 4 is a diagram illustrating four communication conditions according to an embodiment of the present invention.

FIG. 5 is a diagram illustrating verification to an asynchronous interface circuit with aid of a signal generator according to an embodiment of the present invention.

FIG. 6 is a diagram illustrating a MAC frame generated based on control parameters by a signal generator according to an embodiment of the present invention.

FIG. 7 is a diagram illustrating an error occurring on decoding of a physical layer according to an embodiment of the present invention.

FIG. 8 is a diagram illustrating overflow due to a write speed being greater than a read speed according to an embodiment of the present invention.

FIG. 9 is a diagram illustrating underflow due to a write speed being less than a read speed according to an embodiment of the present invention.

FIG. 10 is a diagram illustrating a working flow of a method for verifying an asynchronous interface circuit according to an embodiment of the present invention.

### DETAILED DESCRIPTION

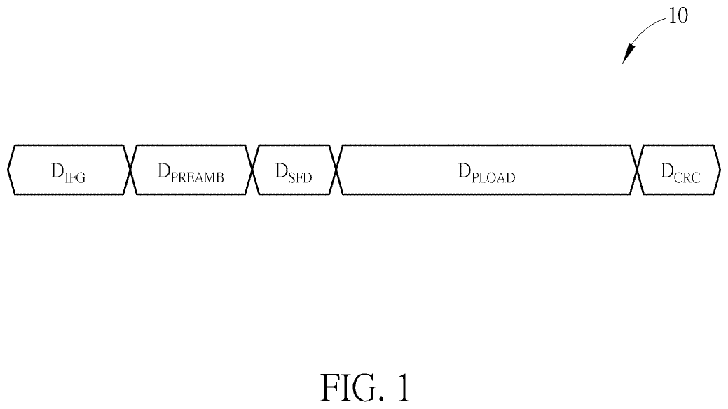

The main function of an Ethernet switch chip is in receiving and forwarding data frames, where a local area network standard used by Ethernet is IEEE 802.3. FIG. 1 is a diagram illustrating a structure of a media access control (MAC) frame 10 of Ethernet according to an embodiment of the present invention. The MAC frame 10 may comprise an inter-frame gap (IFG) D_{IFG}, a preamble D_{PREAMB}, a start of frame delimiter (SFD) D_{SFD}, a frame payload D_{PLOAD} and a check code such as a cyclic redundancy check (CRC) code DCRC, where the IFG D_{IFG} is an idle time reserved between frames to allow circuits to process other flows, and valid data will not be transmitted during this idle time. In addition, a length of the IFG D_{IFG} defined in the local area network standard IEEE 802.3 needs to be greater than or equal to 12 bytes (Bytes), and a length of the preamble D_{PREAMB} needs to be equal to 7 Bytes.

FIG. 2 is a diagram illustrating an asynchronous interface circuit 20 according to an embodiment of the present invention, where the asynchronous interface circuit 20 shown in FIG. 2 simultaneously shows a first data path (as shown by data DATA0_{RX} and DATA0_{TX}) and a second data path (as shown by data DATA1_{RX} and DATA1_{TX}). In particular, reception and transmission of the asynchronous interface circuit 20 may be regarded as two independent behaviors, where clocks for reception and transmission of the asynchronous interface circuit 20 may be asynchronous and correspond to different interface types. For example, on the first data path, the asynchronous interface circuit 20 may receive the data DATA0_{RX} based on a clock signal CLK0_{RX} and transmit the data DATA0_{TX} based on a clock signal CLK0_{TX}, where the clock signals CLK0_{RX} and CLK0_{TX} are asynchronous. In another example, on the second data path, the asynchronous interface circuit 20 may receive the data DATA1_{RX} based on a clock signal CLK1_{RX} and transmit the data DATA1_{TX} based on a clock signal CLK1_{TX}, where the clock signals CLK1_{RX} and CLK1_{TX} are asynchronous. Thus, when frequencies of the clocks for reception and transmission of the asynchronous interface circuit 20 are inaccurate, a probability of error occurrence will significantly increase.

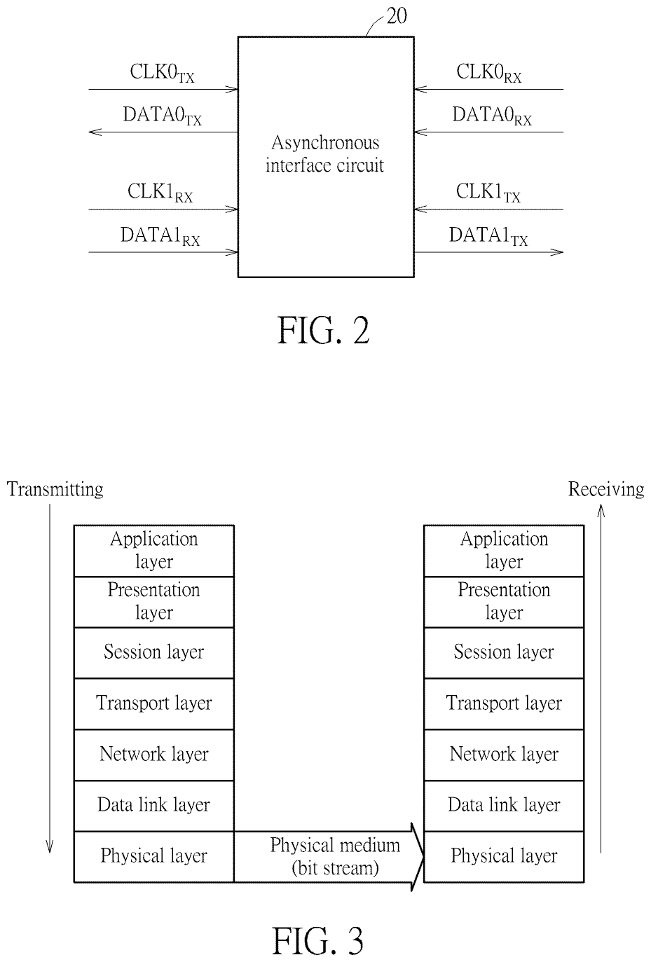

FIG. 3 is a diagram illustrating a MAC frame (e.g. the MAC frame 10) transmitted between two devices via a physical medium according to an embodiment of the present invention. As shown in FIG. 3, a transmitting end may process the MAC frame 10 to be transmitted sequentially through an application layer, a presentation layer, a session layer, a transport layer, a network layer, a data link layer and a physical layer. In particular, the MAC frame 10 is encoded/decoded into a bit stream via the physical layer to allow the physical medium to transmit the bit stream to a receiving end, where after receiving the bit stream, the receiving end may perform corresponding processing sequentially through the physical layer, the data link layer, the network layer, the transport layer, the session layer, the presentation layer and the application layer. It should be noted that an interface type used for transmitting the MAC frame 10 may include, but is not limited to: a media-independent interface (MII), a gigabit media-independent interface (GMII) and a 10-gigabit media-independent interface (XGMII). In order to comply with communication protocols of these interface types, the lengths of the IFG D_{IFG} and/or the preamble D_{PREAMB} in the MAC frame 10 may be increased or decreased after being processed by circuits of the physical layer. In particular, when the MAC frame 10 is transmitted in a system, the MAC frame 10 may pass through many module circuits, and interface types used by these module circuits may be different. In order to enable the MAC frame 10 to successfully pass through each module circuit, the asynchronous interface circuit 20 needs to possess a function of interface type conversion (e.g. GMII to XGMII, XGMII to GMII), where the length of the IFG D_{IFG} is an important parameter for evaluating communication quality, and a smaller fluctuation in the length of the IFG D_{IFG} indicates better communication quality.

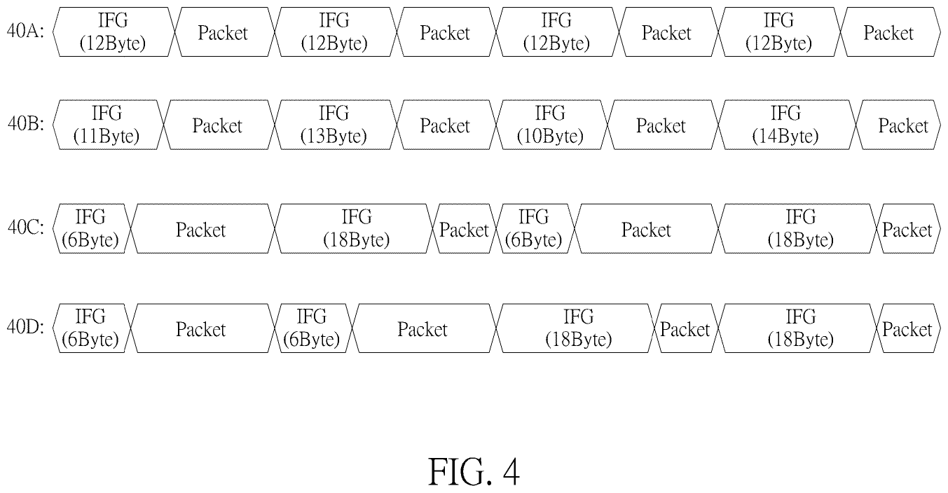

FIG. 4 is a diagram illustrating four communication conditions such as 40A, 40B, 40C and 40D according to an embodiment of the present invention, where when the system operates at full speed, a theoretical average length of the IFG D_{IFG} is 12 Bytes. Although an average IFG length of each of the communication conditions 40A, 40B, 40C and 40D shown in FIG. 4 is 12 Bytes, the communication qualities of the communication conditions 40A, 40B, 40C and 40D are not the same. The communication condition 40A is a standard communication condition conforming to protocol requirements. The IFG length of the communication condition 40B fluctuates around 12 Bytes, while the IFG length of the communication condition 40C has larger fluctuations compared to the communication condition 40B. In addition, although an amplitude of fluctuation of the communication condition 40D is the same as that of the communication condition 40C, the communication condition 40D has consecutive short IFGs (e.g. two consecutive IFGs of 6 Bytes), which causes the greatest impact on the circuit. Thus, the communication quality of the communication condition 40A is the best, the communication condition 40B is the second best, the communication condition 40C is the third best, and the communication condition 40D is the worst. In addition, there may be certain error bytes in the MAC frame 10. When such a non-standard frame is transmitted among a plurality of communication devices, it cannot be ensured that every communication device can correctly identify and forward this non-standard frame, which thereby affects the communication quality.

From the above, it can be seen that the MAC frame 10 received by the asynchronous interface circuit 20 may have various types of conditions. In addition to correctly forward the MAC frame 10, the asynchronous interface circuit 20 sometimes need to further provide a function of improving the communication quality (e.g. adjusting the lengths of the IFG D_{IFG} and/or the preamble D_{PREAMB} of the MAC frame 10), so as to reduce the impact caused by the MAC frame 10 on other communication devices in the network.

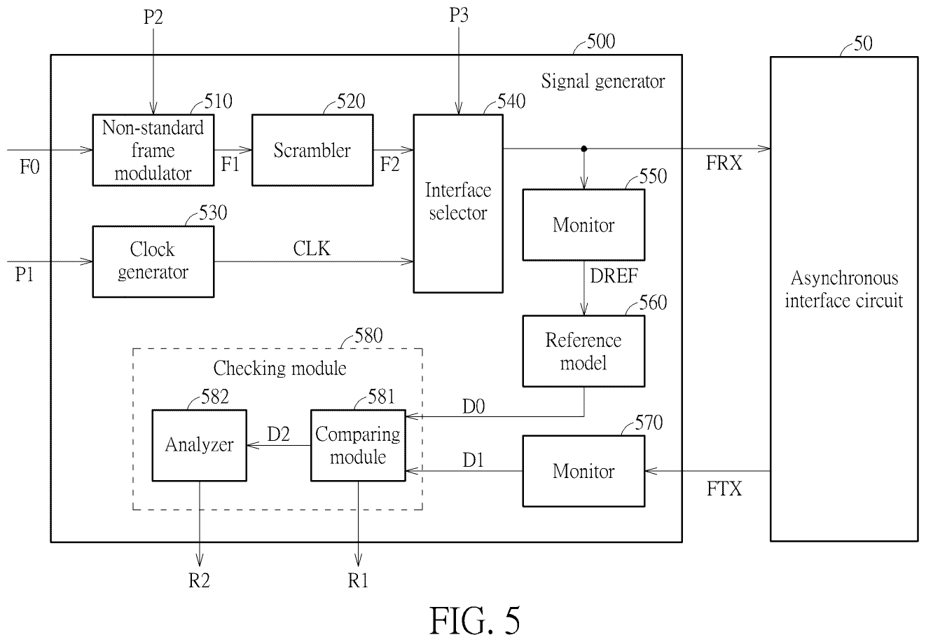

FIG. 5 is a diagram illustrating verification to an asynchronous interface circuit 50 with aid of a signal generator 500 according to an embodiment of the present invention, where the asynchronous interface circuit 50 is coupled to the signal generator 500, and the asynchronous interface circuit 50 may be an example of the asynchronous interface circuit 20 shown in FIG. 2. As shown in FIG. 5, the signal generator 500 may comprise a frame modulator such as a non-standard frame modulator 510, a scrambler 520, a clock generator 530, an interface selector 540, a monitor 550, a reference model 560, a monitor 570 and a checking module 580 (e.g. a checking circuit or a processing circuit executing a program code module associated with checking operations), where the scrambler 520 is coupled between the non-standard frame modulator 510 and the interface selector 540, the clock generator 530 is coupled to the interface selector 540, the monitor 550 is coupled to the interface selector 540, the reference model 560 is coupled to the monitor 550, and the checking module 580 is coupled to the reference model 560 and the monitor 570. In this embodiment, the non-standard frame modulator 510 is configured to modulate a standard frame F0 according to at least one frame control parameter such as a control parameter P2 to generate a modulated signal F1, and the clock generator 530 is configured to generate a clock signal CLK according to at least one clock control parameter such as a control parameter P1. In addition, the interface selector 540 is configured to generate a receiving test signal FRX to the asynchronous interface circuit 50 according to at least one interface control parameter such as a control parameter P3, the modulated signal F1 and the clock signal CLK, where the signal generator 500 may utilize the reference model 560 to generate a reference signal DO according to the receiving test signal FRX, and the asynchronous interface circuit 50 may generate a transmitting test signal FTX according to the receiving test signal FRX. The checking module 580 is configured to generate at least one verification result such as a comparison result R1 and an analysis result R2 according to the reference signal DO and the transmitting test signal FTX.

In this embodiment, the scrambler 520 is configured to scramble contents of the modulated signal F1 to generate a scrambled signal F2, where the interface selector 540 may generate the receiving test signal FRX according to the control parameter P3, the scrambled signal F2 and the clock signal CLK. In addition, the monitors 550 and 570 are configured to monitor the receiving test signal FRX and the transmitting test signal FTX, respectively. For example, the monitor 550 may generate a receiving monitoring signal DREF by monitoring and sampling the receiving test signal FRX, and the monitor 570 may generate a transmitting monitoring signal D1 by monitoring and sampling the transmitting test signal FTX. In particular, the reference model 560 is configured to simulate operations of the asynchronous interface circuit 50, where the reference signal DO outputted by the reference model 560 may be regarded as a theoretical value of the transmitting monitoring signal D1 when the asynchronous interface circuit 50 correctly forwards the receiving test signal FRX as the transmitting test signal FTX.

In this embodiment, the checking module 580 may comprise a comparing module 581 (e.g. a comparing circuit or a processing circuit executing a program code associated with comparing operations) and an analyzer 582 (e.g. a processing circuit which calculates or analyzes data). In particular, the comparing module 581 (which may be regarded as a scoreboard) is configured to check whether the reference signal DO and the transmitting test signal FTX (more particularly, the transmitting monitoring signal D1) are identical to generate the comparison result R1. In addition, when the comparison result R1 indicates that the reference signal DO and the transmitting test signal FTX (more particularly, the transmitting monitoring signal D1) are identical, the analyzer 582 may generate the analysis result R2 according to multiple IFGs within the transmitting test signal FTX. For example, the comparing module 581 may forward the transmitting monitoring signal D1 as a transmitting monitoring signal D2 to the analyzer 582 together with certain control parameters, and the analyzer 582 may generate the analysis result R2 according to IFG information carried by the transmitting monitoring signal D2 (e.g. the multiple IFGs within the transmitting test signal FTX).

In some embodiments, one or more of the non-standard frame modulator 510, the scrambler 520, the clock generator 530, the interface selector 540, the monitor 550, the reference model 560, the monitor 570 and the checking module 580 (e.g. the comparing module 581 and the analyzer 582 therein) may be implemented by hardware (e.g. circuits). In some embodiments, one or more of the non-standard frame modulator 510, the scrambler 520, the clock generator 530, the interface selector 540, the monitor 550, the reference model 560, the monitor 570 and the checking module 580 (e.g. the comparing module 581 and the analyzer 582 therein) may be implemented by firmware. In some embodiments, one or more of the non-standard frame modulator 510, the scrambler 520, the clock generator 530, the interface selector 540, the monitor 550, the reference model 560, the monitor 570 and the checking module 580 (e.g. the comparing module 581 and the analyzer 582 therein) may be implemented by software.

As a receiving clock and a transmitting clock of the asynchronous interface circuit 50 are from different clock sources (e.g. two independent quartz oscillators), various non-ideal conditions may exist in practice. In this embodiment, the control parameter P1 may comprise control parameters ppm_type and Nₚₚₘ, where the clock generator 530 may control a frequency deviation mode for generating the clock signal CLK according to the control parameter ppm_type, and control a frequency deviation amount of the clock signal CLK according to the control parameter Nₚₚₘ. For example, when the clock generator 530 generates the clock signal CLK in a first frequency deviation mode in response to the control parameter ppm_type, the frequency deviation amount of the clock signal CLK may be a typical frequency deviation amount within a range of ±200 parts per million (ppm). In another example, when the clock generator 530 generates the clock signal CLK in a second frequency deviation mode in response to the control parameter ppm_type, the frequency deviation amount of the clock signal CLK may be a random value (e.g. Nₚₚₘ) within the range of ±200 ppm. In particular, setting the clock generator 530 in the first frequency deviation mode can quickly verify working conditions of the asynchronous interface circuit 50 under typical frequency deviations, and setting the clock generator 530 in the second frequency deviation mode can better conform to working conditions of real quartz oscillators. In particular, when a standard frequency of the clock signal CLK is FREQ0 and the frequency deviation amount of the clock signal CLK is Nₚₚₘ, a deviated frequency FREQ1 of the clock signal CLK may be calculated using Equation (1) as follows.

$$FREQ 1 = \frac{1000000 \pm {N}_{p p m}}{1000000} \times FREQ 1 \qquad Equation ( 1 )$$

In addition, the control parameter P2 may comprise control parameters cfg_ifg_min, cfg_ifg_max, cfg_ifg_avg, cfg_ifg_tx_min, cfg_preamble_size, cfg_pkt_len_min, cfg_pkt_len_max, cfg_pkt_len_avg, N_{CRC}, symbol_err, symbol_err_point, check_ifg_min, check_ifg_max, check_ifg_avg, check_ifg_offset, cfg_var_ifg_min and cfg_var_ifg_max. The control parameter cfg_ifg_min may represent a minimum IFG length of transmitted data packets (e.g. the modulated signal F1 or the receiving test signal FRX generated according to the modulated signal F1), the control parameter cfg_ifg_max may represent a maximum IFG length of the transmitted data packets, the control parameter cfg_ifg_avg may represent an average IFG length of the transmitted data packets, the control parameter cfg_ifg_tx_min may represent a minimum IFG length of forwarded data packets (e.g. the reference signal DO or the transmitting monitoring signal D1), the control parameter cfg_preamble_size may represent a preamble length of the transmitted data packets, the control parameter cfg_pkt_len_min may represent a minimum packet length of the transmitted data packets, the control parameter cfg_pkt_len_max may represent a maximum packet length of the transmitted data packets, the control parameter cfg_pkt_len_avg may represent an average packet length of the transmitted data packets, the control parameter N_{CRC} may represent a check code (e.g. a CRC code) of the transmitted data packets, the control parameter symbol_err may represent whether a symbol error such as the aforementioned error byte is inserted into the transmitted data packets, and the control parameter symbol_err point may represent a position where the symbol error is inserted into the transmitted data packets. In addition, the control parameters check_ifg_min, check_ifg_max, check_ifg_avg, check_ifg_offset, cfg_var_ifg_min and cfg_var_ifg_max may be transmitted to the checking module 580 via an internal signal path of the signal generator 500 (e.g. via the reference model 560), for the comparing module 581 and the analyzer 582 to perform comparison and analysis accordingly.

In addition, the interface selector 540 may determine a communication protocol (e.g. a communication protocol conforming to MII, GMII or XGMII) of the receiving test signal FRX according to the control parameter P3, to transmit data packets within the scrambled signal F2 transmitted based on the clock signal CLK to the asynchronous interface circuit 50 using a specified communication protocol. More particularly, MII, GMII and XGMII have different bit widths and are respectively applied in communication scenarios of different speeds. Thus, different interface types and different frequency deviation amounts may correspond to different frequency errors.

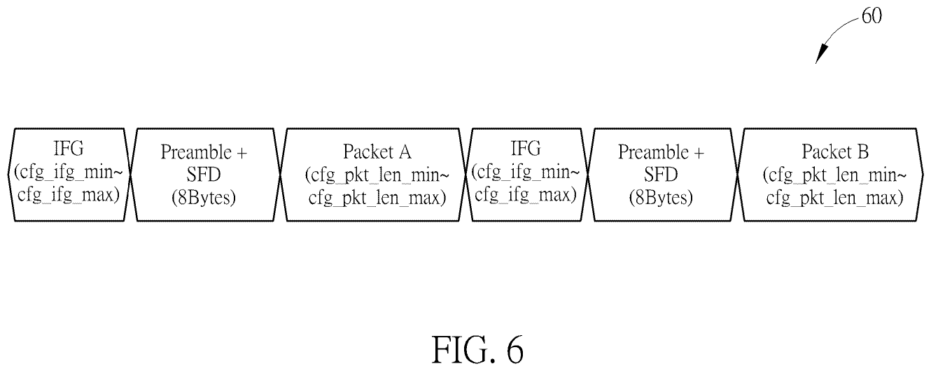

In this embodiment, the signal generator 500 may generate Ethernet packets (e.g. the MAC frame 10) of various conditions according to settings of the control parameters P1, P2 and P3, in order to verify processing of the asynchronous interface circuit 50 on different Ethernet packets, where the signal generator 500 may establish a verification platform based on Universal Verification Methodology (UVM) and execute respective steps. First, the signal generator 500 may define the control parameters P1 and P2 according to characteristics of Ethernet packets to be tested, to modify the standard frame F0 into a required test packet. As shown in a MAC frame 60 shown in FIG. 6, an IFG length of the MAC frame 60 may fall between cfg_ifg_min and cfg_ifg_max, a total length of a preamble and a SFD of the MAC frame 60 is 8 Bytes, and a length of each packet (e.g. a packet A and a packet B) of the MAC frame 60 may fall between cfg_pkt_len_min and cfg_pkt_len_max. Next, the signal generator 500 may select a required interface type at the interface selector 540 via the control parameter P3, in order to transmit the test packet to the asynchronous interface circuit 50 using the specified communication protocol, and transmit the test packet to the reference model 560 via the monitor 550. The comparing module 581 in the checking module 580 may perform a byte-by-byte comparison between packets outputted by the asynchronous interface circuit 50 and packets processed by the reference model 560, to check whether the asynchronous interface circuit 50 can correctly forward contents of the packets. For example, checking items for the packets may comprise: checking whether the preamble (e.g. the preamble D_{PREAMB} shown in FIG. 1) remains unchanged; checking whether content of each byte of the packet (e.g. the frame payload D_{PLOAD} shown in FIG. 1) remains unchanged; checking whether the packet length (e.g. the length of the MAC frame 10 shown in FIG. 1) remains unchanged; checking whether the check code (e.g. the CRC code D_{CRC} shown in FIG. 1) remains unchanged; if there is a symbol error, checking whether the position of the symbol error remains unchanged; and checking whether packets are lost or out of order. When any of the aforementioned checking items indicates that any characteristic of the packet is changed, the comparison result R1 generated by the comparing module 581 may indicate that the packet content is not correctly forwarded. When each of the aforementioned checking items indicates that characteristics of the packet is not changed, the comparison result R1 generated by the comparing module 581 may indicate that the packet content has been correctly forwarded, and the analyzer 582 may further record the length of the IFG of each packet (e.g. the length of the IFG D_{IFG} shown in FIG. 1) and perform analysis accordingly to generate the analysis result R2.

In some embodiments, the analyzer 582 may perform a first analysis operation, such as checking whether each of the multiple IFGs within the transmitting test signal FTX (e.g. the transmitting monitoring signal D1), such as N IFGs IFG1, IFG2, . . . and IFGN, conforms to a corresponding IFG within the reference signal DO, to generate a first analysis sub-result within the analysis result R2, where when any IFG IFGₙ (n is a positive integer in an interval [1, N]) within the transmitting test signal FTX (e.g. the transmitting monitoring signal D1) is inconsistent with the corresponding IFG within the reference signal DO, the analyzer 582 may issue an error alert via the first analysis sub-result.

In some embodiments, the analyzer 582 may perform a second analysis operation, such as checking whether an average value of the IFGs IFG1, IFG2, . . . and IFGN conforms to a theoretical value determined according to the control parameter P2 (e.g. the control parameters cfg_ifg_avg and/or cfg_pkt_len_avg) and the control parameter P1 (e.g. the control parameter Nₚₚₘ), to generate a second analysis sub-result of the analysis result R2. In particular, after the MAC frame 60 is forwarded through a synchronous interface circuit, the average value of its IFGs IFG₁, IFG₂, . . . and IFG_{N} is theoretically equal to the control parameter cfg_ifg_avg. After the MAC frame 60 is forwarded through an asynchronous interface circuit (e.g. the asynchronous interface circuit 50), the average value of its IFGs IFG₁, IFG₂, . . . and IFG_{N} will theoretically be close to cfg_ifg_avg±(cfg_pkt_len_avg×(Nₚₚₘ/1000000)). Thus, when the average value of the IFGs IFG₁, IFG₂, . . . and IFG_{N} deviates from the aforementioned theoretical value (e.g. a difference is greater than a predetermined value), the analyzer 582 may issue an error alert via the second analysis sub-result.

In some embodiments, the analyzer 582 may perform a third analysis operation, such as checking whether each of the IFGs IFG₁, IFG₂, . . . and IFG_{N} is not less than a minimum IFG length determined according to the control parameter P2 (e.g. the control parameter check_ifg_min), to generate a third analysis sub-result of the analysis result R2. When the length of any IFG IFGₙ among the IFGs IFG₁, IFG₂, . . . and IFG_{N} is less than check_ifg_min, the analyzer 582 may issue an error alert via the third analysis sub-result.

In some embodiments, the analyzer 582 may perform a fourth analysis operation, such as checking whether the IFGs IFG₁, IFG₂, . . . and IFG_{N} comprise multiple consecutive deviated IFGs, to generate a fourth analysis sub-result of the analysis result R2, where a length of each deviated IFG of the multiple consecutive deviated IFGs falls in a deviation interval determined according to the control parameter P2. For example, the deviation interval may be defined as an interval between check_ifg_min and (check_ifg_min+check_ifg_offset). When lengths of multiple consecutive IFGs included in the IFGs IFG₁, IFG₂, . . . and IFG_{N} fall in the interval between check_ifg_min and (check_ifg_min+check_ifg_offset), the analyzer 582 may issue an error alert via the fourth analysis sub-result.

In some embodiments, the analyzer 582 may perform a fifth analysis operation, such as calculating a variance S2 of the IFGs IFG₁, IFG₂, . . . and IFG_{N}, to generate a fifth analysis sub-result of the analysis result R2. A larger variance S2 indicates larger fluctuations in the lengths of the IFGs IFG₁, IFG₂, . . . and IFG_{N}, which means a worse communication quality. A method of calculating the variance S2 of the IFGs IFG₁, IFG₂, . . . and IFG_{N} is shown in the following Equations (2), (3) and (4).

$${X}_{n} = \{ \begin{matrix}cfg\_var \_ifg \_min - {IFG}_{n} , when {IFG}_{n} < cfg\_var \_ifg \_min \\ 0 , when cfg\_var \_ifg \_min < {IFG}_{n} < cfg\_var \_ifg \_max \\ {IFG}_{n} - cfg\_var \_ifg \_max , when cfg\_var \_ifg \_max < {IFG}_{n}\end{matrix} \qquad Equation ( 2 )$$

$$\overline{X} = \frac{{\sum }_{i = 1}^{N} {X}_{i}}{N} \qquad Equation ( 3 )$$

$${S}^{2} = \frac{{\sum }_{i = 1}^{N} {( {X}_{i} - \overline{X} )}^{2}}{N} \qquad Equation ( 4 )$$

Equation (2) calculates a deviation value of the IFG of the n^{th} frame (the analyzer 582 allows the IFG IFGₙ to deviate within an interval between cfg_var_ifg_min and cfg_var_ifg_max), Equation (3) calculates an average deviation value of the IFGs IFG₁, IFG₂, . . . and IFG_{N}, and Equation (4) calculates the variance S2 of the IFGs IFG₁, IFG₂, . . . and IFG_{N}. Based on the aforementioned packet configuration and corresponding comparison/analysis mechanisms, the signal generator 500 can test performance of the asynchronous interface circuit 50 when receiving packets of various characteristics.

In one embodiment, the signal generator 500 may perform a test of standard frame Ethernet packets passing through a synchronous interface on the asynchronous interface circuit 50. In particular, the signal generator 500 may construct a synchronized clock scenario according to the control parameter P1, and construct standard Ethernet packets according to the control parameter P2 (e.g. Ethernet packets where IFGs are all 12 Bytes and packet lengths all fall in an interval between 64 Bytes and 1518 Bytes). The comparing module 581 may determine whether the Ethernet packets outputted by the reference model 560 and the Ethernet packets outputted by the asynchronous interface circuit 50 are identical, in order to check whether the Ethernet packets can be correctly forwarded by the asynchronous interface circuit 50. After passing the check of the comparing module 581, the analyzer 582 may perform the first analysis operation mentioned above to check the length of each IFG.

In one embodiment, the signal generator 500 may perform a test of standard frame Ethernet packets passing through an asynchronous interface on the asynchronous interface circuit 50. In particular, the signal generator 500 may construct an asynchronous clock scenario according to the control parameter P1, and construct standard Ethernet packets according to the control parameter P2 (e.g. Ethernet packets where IFGs are all 12 Bytes and packet lengths all fall in an interval between 64 Bytes and 1518 Bytes). The comparing module 581 may determine whether the Ethernet packets outputted by the reference model 560 and the Ethernet packets outputted by the asynchronous interface circuit 50 are identical, in order to check whether the Ethernet packets can be correctly forwarded by the asynchronous interface circuit 50. After passing the check of the comparing module 581, the analyzer 582 may perform associated checks of IFGs of the second analysis operation, the third analysis operation, the fourth analysis operation and the fifth analysis operation mentioned above.

In one embodiment, the signal generator 500 may perform a test of interface conversion of standard frame Ethernet packets passing through an asynchronous interface on the asynchronous interface circuit 50. In particular, the signal generator 500 may construct an asynchronous clock scenario according to the control parameter P1, and construct standard Ethernet packets according to the control parameter P2 (e.g. Ethernet packets where IFGs are all 12 Bytes and packet lengths all fall in an interval between 64 Bytes and 1518 Bytes). In addition, the signal generator 500 may utilize a first type interface (e.g. GMII) to transmit the Ethernet packets to the asynchronous interface circuit 50 and utilize a second type interface (e.g. XGMII) to receive the Ethernet packets from the asynchronous interface circuit 50 according to the control parameter P3, in order to check the interface type conversion function of the asynchronous interface circuit 50. More particularly, the comparing module 581 may determine whether contents and characteristics of the Ethernet packets change due to the interface type conversion of the asynchronous interface circuit 50. After passing the check of the comparing module 581, the analyzer 582 may perform the associated checks of IFGs of the second analysis operation, the third analysis operation, the fourth analysis operation and the fifth analysis operation mentioned above.

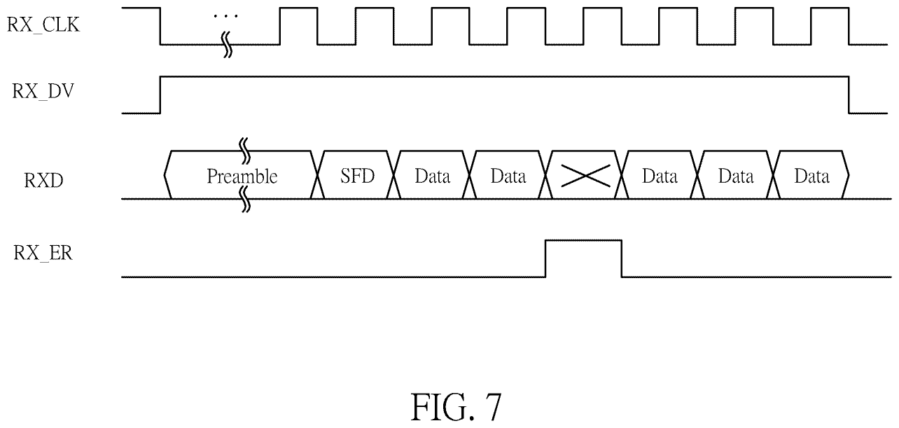

In a communication network, after Ethernet packets pass through various asynchronous interfaces, it is difficult for the IFGs therein to maintain a standard length (e.g. 12 Bytes) at all times. If the IFG is too long, the transmission rate will be affected. If the IFG is too short, there will be risks of data collision and loss. In addition, when the frequency of the quartz oscillator is inaccurate, variation in the lengths of transmitted packets will also affect the asynchronous interface (e.g. when the frequency deviation amount is too large and the packet length is too long, the asynchronous interface cannot compensate in the IFG in time, which leads to buffer space being empty or full, causing errors). In addition, due to limitations of transmission system design, one or more frames are inevitably corrupted during transmission (e.g. occurrences of bit errors), causing the receiving end to receive incorrect data. For example, FIG. 7 is a diagram illustrating occurrence of errors in encoding of a physical layer of GMII according to an embodiment of the present invention, where a clock signal RX_CLK may be an example of the clock signal CLK shown in FIG. 5, a data signal RXD may be an example of the Ethernet packets within the receiving test signal FRX shown in FIG. 5, an interval where a control signal RX_DV has a high logic level (e.g. a logic value “1”) may represent a period where the data signal RXD is valid, and an interval where an error indication signal RX_ER has the high logic level may represent a position of a symbol error of the data signal RXD. In particular, when an error occurs in the encoding of the physical layer, a MAC layer may pull the error indication signal RX ER to the high logic level during a process of receiving data to indicate the position of the symbol error of the data signal RXD. Through configurations of the control parameters P1, P2 and P3, the signal generator 500 can accordingly generate non-standard frames of various conditions (e.g. IFG is not equal to 12 Bytes, packet length does not fall in the interval between 64 Bytes and 1518 Bytes, or having symbol errors), in order to test whether packet forwarding of the asynchronous interface circuit 50 is normal, and utilize the analyzer 582 to determine communication quality of the asynchronous interface circuit 50 forwarding the non-standard frames.

In one embodiment, the signal generator 500 may perform a test of non-standard frame Ethernet packets passing through an asynchronous interface on the asynchronous interface circuit 50. In particular, the signal generator 500 may construct an asynchronous clock scenario according to the control parameter P1, and construct the characteristics of the Ethernet packets (e.g. the IFG length and the packet length) according to the control parameter P2. The comparing module 581 may determine whether the Ethernet packets outputted by the reference model 560 and the Ethernet packets outputted by the asynchronous interface circuit 50 are identical, in order to check whether the Ethernet packets can be correctly forwarded by the asynchronous interface circuit 50 (e.g. checking whether packet contents change and checking whether packets are lost). After passing the check of the comparing module 581, the analyzer 582 may perform associated checks of IFGs of the second analysis operation, the third analysis operation, the fourth analysis operation and the fifth analysis operation mentioned above. After passing the aforementioned checking items, the control parameters symbol_err and symbol_err point may be further set (e.g. pulling the control parameter symbol_err to the logic value “1” to enable insertion of symbol errors), such that the signal generator 500 further generates Ethernet packets having a symbol error at a specific position according to the control parameters symbol_err and symbol_err_point. The comparing module 581 may determine whether the Ethernet packets outputted by the reference model 560 and the Ethernet packets outputted by the asynchronous interface circuit 50 are identical, in order to check whether the Ethernet packets can be correctly forwarded by the asynchronous interface circuit 50 (e.g. checking whether packet contents change and whether the position of the symbol error changes).

In addition, non-standard frames are more likely to incur errors when passing through different interface types. For example, in a case of GMII to XGMII, the position of the SFD D_{SFD} needs to be adjusted and the length of the IFG D_{IFG} may change, such that the frequency deviation of the clock signal CLK may cause a severe impact on the IFG D_{IFG}. Thus, it is required to ensure that the asynchronous interface circuit 50 does not change contents of the MAC frame 10 (e.g. change the length of the MAC frame 10, change the check code D_{CRC} of the MAC frame 10, generate additional errors or change the position of the symbol error) when performing interface type conversion.

In one embodiment, the signal generator 500 may perform a test of interface conversion of non-standard frame Ethernet packets passing through an asynchronous interface on the asynchronous interface circuit 50. In particular, the signal generator 500 may construct an asynchronous clock scenario according to the control parameter P1, and enable the interface type conversion function (e.g. GMII to XGMII) according to the control parameter P3. Furthermore, the signal generator 500 may construct the characteristics of the Ethernet packets (e.g. the IFG length and the packet length) according to the control parameter P2. The comparing module 581 may determine whether the contents and the characteristics of the Ethernet packets change when being forwarded through the asynchronous interface circuit 50, and check whether the Ethernet packets are lost. After passing the aforementioned checking items, the control parameters symbol_err and symbol_err point can be further set (e.g. pulling the control parameter symbol_err to the logic value “1” to enable insertion of symbol errors), such that the signal generator 500 further generates Ethernet packets having a symbol error at a specific position according to the control parameters symbol_err and symbol_err point. The comparing module 581 may check whether the Ethernet packets can be correctly forwarded by the asynchronous interface circuit 50, and more particularly, check whether Ethernet packets having symbol errors can be correctly forwarded (e.g. checking whether packet contents change and whether the position of the symbol error changes). After passing the check of the comparing module 581, the analyzer 582 may perform associated checks of IFGs of the second analysis operation, the third analysis operation, the fourth analysis operation and the fifth analysis operation mentioned above.

In addition, the minimum IFG of Ethernet is to ensure stability and performance of data transmission. When the IFG is too small, collision may occur between MAC frames, leading to data loss. For example, in an asynchronous first-in first-out (FIFO) buffer in the asynchronous interface 50, when a read speed and a write speed are inconsistent, data overflow or data underflow may occur.

FIG. 8 is a diagram illustrating occurrence of data overflow in an asynchronous FIFO buffer 80 due to a write speed being greater than a read speed according to an embodiment of the present invention, where a read pointer is marked on the left side and a write pointer is marked on the right side to indicate that the write speed is greater than the read speed. As shown in FIG. 8, data data0, data1, data2, data3, data4, . . . , data22 and data23 are written into addresses addr0, addr1, addr2, addr3, addr4, . . . , addr22 and addr23 of the asynchronous FIFO buffer 80, respectively. New data0, data1, data2 and data3 (labeled “data0 (new)”, “data1 (new)”, “data2 (new)” and “data3 (new)” in FIG. 8 for better comprehension) have been written into the asynchronous FIFO buffer 80 and a new data4 is going to be written, but the old data4 has not been read yet, leading to data overflow (e.g. the old data4 is lost). In particular, whether data overflow will occur can be determined by the following Equation (5).

$$cfg\_ifg \_avg - cfg\_ifg \_tx \_min \times ( 1 + \frac{{N}_{p p m}}{1000000} ) - cfg\_pkt \_len \_avg \times ( \frac{{N}_{p p m}}{1000000} ) \qquad Equation ( 5 )$$

When a calculation result of Equation (5) is greater than or equal to 0, this indicates that data overflow will not occur. When the calculation result of Equation (5) is less than 0, this indicates that data overflow will occur. In addition, the following Equation (6) can calculate a moment overflowcnt1 (indicating that data overflow occurs at the overflowcnt1-th packet) at which data overflow occurs for different types of Ethernet packets when the write speed is greater than the read speed.

$$overflowcnt 1 = \frac{{N}_{d e e p} - W L - cfg\_pkt \_len \_avg \times ( \frac{{N}_{p p m}}{1000000} )}{( cfg\_pkt \_len \_avg + cfg\_ifg \_avg ) \times ( \frac{{N}_{p p m}}{1000000} ) + cfg\_ifg \_tx \_min \times ( 1 + ( \frac{{N}_{p p m}}{1000000} ) ) - cfg\_ifg \_avg} + 1 \qquad Equation ( 6 )$$

N_{deep} may represent a depth parameter of the asynchronous FIFO buffer (e.g. the asynchronous FIFO buffer 80). When a width of the asynchronous FIFO buffer (e.g. the asynchronous FIFO buffer 80) is M, it means that this asynchronous buffer can store at most N_{deep} sets of M-bit data. In addition, WL may represent a water level parameter of the asynchronous FIFO buffer (e.g. the asynchronous FIFO buffer 80), where a read operation of this asynchronous FIFO buffer is performed after WL clock cycles after the Ethernet packet is written. Based on calculations of Equations (5) and (6), it can be known that when the average length of Ethernet packets (i.e. cfg_pkt_len_avg) is 64 Bytes, the average length of IFG (i.e. cfg_ifg_avg) is 5 Bytes, the water level parameter WL is 3, the depth parameter N_{deep} is 24, and a target length of IFG expected to be compensated (i.e. cfg_ifg_tx_min) is 5 Bytes, data overflow will theoretically occur at the 1420th Ethernet packet under a condition where the frequency deviation amount is 200 ppm. In addition, when the average length of IFG (i.e. cfg_ifg_avg) is 6 Bytes while other conditions remain unchanged, data overflow will theoretically not occur.

In one embodiment, the signal generator 500 may verify a limit value of IFG based on a condition where writing is faster than reading. In particular, the signal generator 500 may construct a scenario where writing is faster than reading according to the control parameter P1, and construct the characteristics of the Ethernet packets (e.g. the IFG length and the packet length, and more particularly, setting the IFG length to cfg_ifg_min) according to the control parameter P2. The comparing module 581 may determine whether the status of the Ethernet packets outputted by the asynchronous interface circuit 50 (e.g. whether data overflow occurs and the moment at which data overflow occurs) conforms to theoretical values provided by the reference model 560 (e.g. theoretical values calculated via Equation (5) and Equation (6)). In addition, after adjusting the control parameter cfg_ifg_min, the signal generator 500 may construct the characteristics of the Ethernet packets (more particularly, changing the length of IFG) again according to the control parameter P2, and utilize the comparing module 581 to determine the status of the Ethernet packets outputted by the asynchronous interface circuit 50 after the length of IFG is changed. Through the aforementioned operations, the signal generator 500 may obtain the limit value of IFG under the condition where writing is faster than reading. For example, when the average length (i.e. cfg_pkt_len_avg) of the Ethernet packets is 64 Bytes, the water level parameter WL is 3, the depth parameter N_{deep} is 24, and the target length of IFG expected to be compensated (i.e. cfg_ifg_tx_min) is 5 Bytes, if the length of IFG (e.g. cfg_ifg_avg or cfg_ifg_min) is greater than or equal to 6 Bytes, data overflow will not occur. In addition, although the Ethernet packet at the moment at which data overflow occurs has errors, reception of subsequent Ethernet packets will not be affected, and the signal generator 500 can utilize the comparing module 581 to perform associated checks.

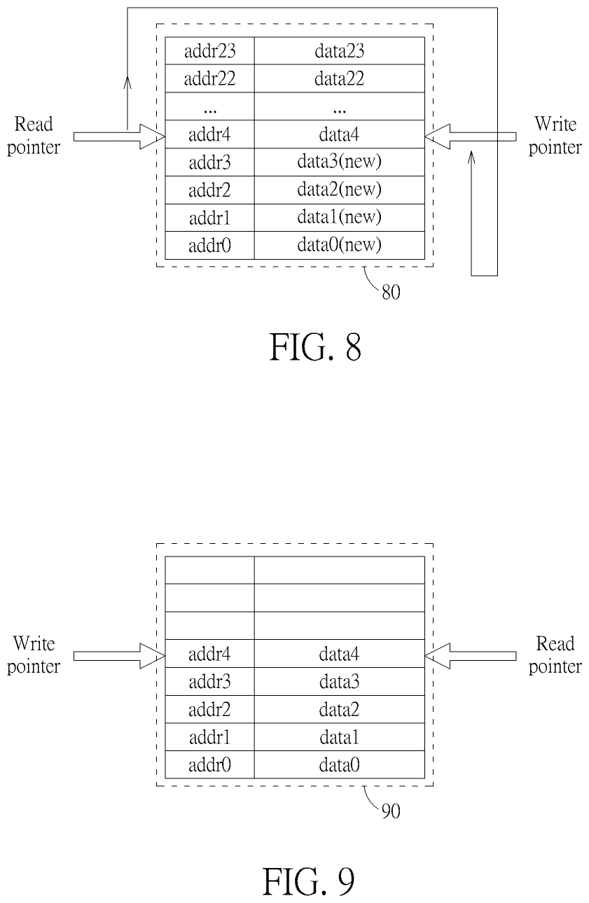

FIG. 9 is a diagram illustrating occurrence of data underflow in the asynchronous FIFO buffer 80 due to the write speed being less than the read speed according to an embodiment of the present invention, where the read pointer is marked on the right side and the write pointer is marked on the left side to indicate that the write speed is less than the read speed. As shown in FIG. 9, data data0, data1, data2, data3 and data4 are written into addresses addr0, addr1, addr2, addr3 and addr4 of an asynchronous FIFO buffer 90, respectively. As data after data4 has not been written yet but data4 has already been read, if reading continues at this moment, invalid data will be read out and data underflow occurs. The following Equation (7) may calculate a moment underflowcnt (indicating that data underflow occurs at the underflowcnt-th packet) at which data underflow occurs for different types of Ethernet packets when the write speed is less than the read speed.

$$overflowcnt = 1 + \frac{W L}{( cfg\_pkt \_len \_avg + cfg\_ifg \_avg ) \times \frac{{N}_{p p m}}{1000000}} \qquad Equation ( 7 )$$

It should be noted that under the condition where the write speed is less than the read speed, if the IFG is shortened to be less than the target length of IFG expected to be compensated (i.e. cfg_ifg_tx_min), after accumulation of Ethernet packets, a gap between the read pointer and the write pointer may exceed the depth of the asynchronous FIFO buffer, causing occurrence of data overflow as well. Whether data overflow will occur can be determined by the following Equation (8).

$$cfg\_ifg \_avg \times ( 1 + \frac{{N}_{p p m}}{1000000} ) + ( cfg\_pkt \_len \_avg \times \frac{{N}_{p p m}}{1000000} ) - cfg\_ifg \_tx \_min \qquad Equation ( 8 )$$

When a calculation result of Equation (8) is greater than or equal to 0, this indicates that data overflow will not occur. When the calculation result of Equation (8) is less than 0, this indicates that data overflow will occur. In addition, the following Equation (9) may calculate a moment overflowcnt2 (indicating that data overflow occurs at the overflowcnt2-th packet) at which data overflow occurs for different types of Ethernet packets when the write speed is less than the read speed.

$$overflowcnt 2 = \frac{{N}_{d e e p} - WL}{cfg\_ifg \_tx \_min - ( cfg\_ifg \_avg \times ( \frac{{N}_{p p m}}{1000000} ) + cfg\_pkt \_len \_avg \times \frac{{N}_{p p m}}{1000000} )} + 1 \qquad Equation ( 9 )$$

Based on calculations of Equations (8) and (9), it can be known that when the average length of the Ethernet packets (i.e. cfg_pkt_len_avg) is 64 Bytes, the average length of IFG (i.e. cfg_ifg_avg) is 4 Bytes, the water level parameter WL is 3, the depth parameter N_{deep} is 24, and the target length of IFG expected to be compensated (i.e. cfg_ifg_tx_min) is 5 Bytes, data overflow will theoretically occur at the 22^{nd} Ethernet packet under a condition where the frequency deviation amount is 200 ppm. In addition, when the average length of IFG (i.e. cfg_ifg_avg) is 5 Bytes while other conditions remain unchanged, data overflow will theoretically not occur.

In one embodiment, the signal generator 500 may verify a limit value of IFG based on the condition where writing is slower than reading. In particular, the signal generator 500 may construct a scenario where writing is slower than reading according to the control parameter P1, and construct the characteristics of the Ethernet packets (e.g. the IFG length and the packet length, and more particularly, setting the IFG length to cfg_ifg_min) according to the control parameter P2. The comparing module 581 may determine whether the status of Ethernet packets outputted by the asynchronous interface circuit 50 (e.g. whether data overflow or data underflow occurs and the moment at which data overflow or data underflow occurs) conforms to theoretical values provided by the reference model 560 (e.g. theoretical values calculated via Equation (8) and Equation (9)). In addition, after adjusting the control parameter cfg_ifg_min, the signal generator 500 may construct the characteristics of the Ethernet packets (more particularly, changing the length of IFG) again according to the control parameter P2, and utilize the comparing module 581 to determine the status of the Ethernet packets outputted by the asynchronous interface circuit 50 after the length of IFG is changed. Through the aforementioned operations, the signal generator 500 may obtain the limit value of IFG under the condition where writing is slower than reading. In addition, although the Ethernet packet at the moment at which data overflow or data underflow occurs has errors, reception of subsequent Ethernet packets should not be affected, and the signal generator 500 may utilize the comparing module 581 to perform associated checks.

In Ethernet, when a packet length is less than 64 Bytes, this packet may be referred to as a runt packet (or a fragment packet); and when a packet length is greater than 1518 Bytes, this packet may be referred to as a jumbo packet (or an oversized packet). Both runt packets and jumbo packets are abnormal Ethernet packets and can cause a great impact on the asynchronous interface. The signal generator 500 may utilize the scrambler 520 to change the packet length (e.g. changing the length of packets in the modulated signal F1) to generate runt packets with the length less than 64 Bytes and jumbo packets with the length greater than 1518 Bytes in the scrambled signal F2. When the asynchronous interface circuit 50 receives these scrambled packets (e.g. the runt packets and the jumbo packets), a reset function may be triggered. After the asynchronous interface circuit 50 is reset, the signal generator 500 may transmit normal packets (e.g. packets with the length between 64 Bytes and 1518 Bytes) to the asynchronous interface circuit 50, in order to check whether the asynchronous interface circuit 50 can recover by itself and normally receive/forward these normal packets after suffering the impact of a large number of scrambled packets.

In addition, the signal generator 500 may utilize the scrambler 520 to continuously generate scrambled packets with the IFG length less than cfg_ifg_min. After the asynchronous interface circuit 50 receives these scrambled packets and the reset function is triggered, the signal generator 500 may transmit normal packets (e.g. packets with the IFG length greater than cfg_ifg_min) to the asynchronous interface circuit 50, in order to check whether the asynchronous interface circuit 50 can recover by itself and normally receive/forward these normal packets after suffering the impact of a large number of scrambled packets.

In addition, the signal generator 500 may utilize the scrambler 520 to continuously generate scrambled packets with the preamble length less than a minimum length specified by the IEEE 802.3 standard (e.g. 7 Bytes). After the asynchronous interface circuit 50 receives these scrambled packets and the reset function is triggered, the signal generator 500 may transmit normal packets (e.g. packets with the preamble length conforming to the IEEE 802.3 standard) to the asynchronous interface circuit 50, in order to check whether the asynchronous interface circuit 50 can recover by itself and normally receive/forward these normal packets after suffering the impact of a large number of scrambled packets.

In addition, the signal generator 500 may randomly insert the scrambled packets mentioned above (e.g. the runt packets, the jumbo packets, the scrambled packets with too short IFG and/or the scrambled packets with too short preamble) during a process of transmitting normal packets without being scrambled by the scrambler 520 to the asynchronous interface circuit 50, in order to check whether the asynchronous interface circuit 50 can correctly process a small amount of scrambled packets (e.g. checking whether the asynchronous interface circuit 50 will be disturbed by the scrambled packets to the extent that it cannot work normally).

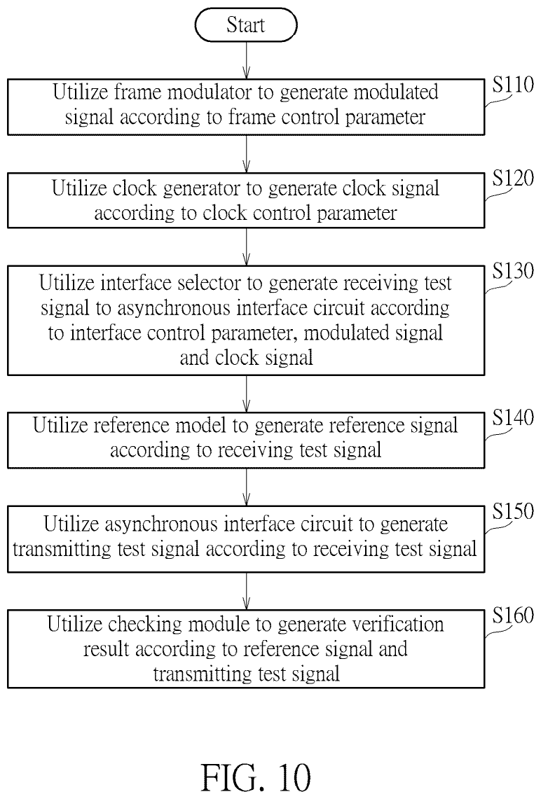

FIG. 10 is a diagram illustrating a working flow of a method for verifying an asynchronous interface circuit (e.g. the asynchronous interface circuit 50 shown in FIG. 5) according to an embodiment of the present invention, where the asynchronous interface circuit is coupled to a signal generator (e.g. the signal generator 500 shown in FIG. 5). It should be noted that the working flow shown in FIG. 10 is for illustrative purposes only, and is not meant to be a limitation of the present invention. For example, one or more steps may be added, deleted, or modified in the working flow shown in FIG. 10. In addition, if a same result can be obtained, these steps do not have to be executed in the exact order shown in FIG. 10.

In Step S110, the signal generator may utilize a frame modulator therein (e.g. the non-standard frame modulator 510 shown in FIG. 5) to generate a modulated signal according to at least one frame control parameter.

In Step S120, the signal generator may utilize a clock generator therein (e.g. the clock generator 530 shown in FIG. 5) to generate a clock signal according to at least one clock control parameter.

In Step S130, the signal generator may utilize an interface selector therein (e.g. the interface selector 540 shown in FIG. 5) to generate a receiving test signal to the asynchronous interface circuit according to at least one interface control parameter, the modulated signal and the clock signal.

In Step S140, the signal generator may utilize a reference model therein (e.g. the reference model 560 shown in FIG. 5) to generate a reference signal according to the receiving test signal.

In Step S150, the signal generator may utilize the asynchronous interface circuit to generate a transmitting test signal according to the receiving test signal.

In Step S160, the signal generator may utilize a checking module therein (e.g. the checking module 580 shown in FIG. 5) to generate at least one verification result according to the reference signal and the transmitting test signal.

In summary, the signal generator 500 and the method provided by the embodiments of the present invention can generate Ethernet packets of various conditions, in order to check whether the asynchronous interface circuit 50 can properly forward these Ethernet packets under these conditions and further analyze the communication quality thereof. In addition, by repeatedly adjusting settings of the signal generator 500 (e.g. settings of the control parameters P1, P2 and/or P3), test packets of various extreme conditions can be transmitted to the asynchronous interface circuit 50, in order to test the performance limits of the asynchronous interface circuit 50. Thus, in comparison with the related arts, the embodiments of the present invention can verify the performance of the asynchronous interface circuit 50 more comprehensively.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A signal generator for verifying an asynchronous interface circuit, comprising:
a frame modulator, configured to generate a modulated signal according to at least one frame control parameter;
a clock generator, configured to generate a clock signal according to at least one clock control parameter;
an interface selector, configured to generate a receiving test signal to the asynchronous interface circuit according to at least one interface control parameter, the modulated signal and the clock signal, wherein the signal generator utilizes a reference model to generate a reference signal according to the receiving test signal, and the asynchronous interface circuit generates a transmitting test signal according to the receiving test signal;
a checking module, configured to generate at least one verification result according to the reference signal and the transmitting test signal.

2. The signal generator of claim 1, wherein the checking module comprises:
a comparing module, configured to check whether the reference signal and the transmitting test signal are identical to generate a comparison result within the at least one verification result.

3. The signal generator of claim 2, wherein the checking module further comprises:
an analyzer, wherein when the comparison result indicates that the reference signal and the transmitting test signal are identical, the analyzer generates an analysis result within the at least one verification result according to multiple inter-frame gaps (IFGs) within the transmitting test signal.

4. The signal generator of claim 3, wherein the analyzer checks whether each of the multiple IFGs within the transmitting test signal conforms to a corresponding IFG within the reference signal, in order to generate the analysis result.

5. The signal generator of claim 3, wherein the analyzer checks whether an average value of the multiple IFGs conforms to a theoretical value determined according to the at least one frame control parameter and the at least one clock control parameter, in order to generate the analysis result.

6. The signal generator of claim 3, wherein the analyzer checks whether each of the multiple IFGs is not less than a minimum IFG length determined according to the at least one frame control parameter, in order to generate the analysis result.

7. The signal generator of claim 3, wherein the analyzer checks whether the multiple IFGs comprises multiple consecutive deviated IFGs, in order to generate the analysis result, and a length of each deviated IFG of the multiple consecutive deviated IFGs falls in a deviation interval determined according to the at least one frame control parameter.

8. The signal generator of claim 3, wherein the analyzer calculates a variance of the multiple IFGs, in order to generate the analysis result.

9. The signal generator of claim 1, further comprising:
a scrambler, coupled between the frame modulator and the interface selector, configured to scramble contents of the modulated signal to generate a scrambled signal;
wherein the interface selector generates the receiving test signal according to the at least one interface control parameter, the scrambled signal and the clock signal.

10. A method for verifying an asynchronous interface circuit, wherein the asynchronous interface circuit is coupled to a signal generator, and the method comprises:
utilizing a frame modulator of the signal generator to generate a modulated signal according to at least one frame control parameter;
utilizing a clock generator of the signal generator to generate a clock signal according to at least one clock control parameter;
utilizing an interface selector of the signal generator to generate a receiving test signal to the asynchronous interface circuit according to at least one interface control parameter, the modulated signal and the clock signal;
utilizing a reference model of the signal generator to generate a reference signal according to the receiving test signal;
utilizing the asynchronous interface circuit to generate a transmitting test signal according to the receiving test signal; and
utilizing a checking module of the signal generator to generate at least one verification result according to the reference signal and the transmitting test signal.

11. The method of claim 10, wherein utilizing the checking module of the signal generator to generate the at least one verification result according to the reference signal and the transmitting test signal comprises:
utilizing a comparing module of the checking module to check whether the reference signal and the transmitting test signal are identical to generate a comparison result within the at least one verification result.

12. The method of claim 11, wherein utilizing the checking module of the signal generator to generate the at least one verification result according to the reference signal and the transmitting test signal comprises:
in response to the comparison result indicating that the reference signal and the transmitting test signal are identical, utilizing an analyzer of the checking module to generate an analysis result within the at least one verification result according to multiple inter-frame gaps (IFGs) within the transmitting test signal.

13. The method of claim 12, wherein the analyzer checks whether each of the multiple IFGs within the transmitting test signal conforms to a corresponding IFG within the reference signal, in order to generate the analysis result.

14. The method of claim 12, wherein the analyzer checks whether an average value of the multiple IFGs conforms to a theoretical value determined according to the at least one frame control parameter and the at least one clock control parameter, in order to generate the analysis result.

15. The method of claim 12, wherein the analyzer checks whether each of the multiple IFGs is not less than a minimum IFG length determined according to the at least one frame control parameter, in order to generate the analysis result.

16. The method of claim 12, wherein the analyzer checks whether the multiple IFGs comprises multiple consecutive deviated IFGs, in order to generate the analysis result, and a length of each deviated IFG of the multiple consecutive deviated IFGs falls in a deviation interval determined according to the at least one frame control parameter.

17. The method of claim 12, wherein the analyzer calculates a variance of the multiple IFGs, in order to generate the analysis result.

18. The method of claim 10, further comprising:
utilizing a scrambler of the signal generator to scramble contents of the modulated signal to generate a scrambled signal;
wherein the interface selector generates the receiving test signal according to the at least one interface control parameter, the scrambled signal and the clock signal.
